(19) United States
(12) Patent Application Publication
(10) Pub. No.: US 2024/0429043 A1
(43) Pub. Date: Dec. 26, 2024

(54) METHOD OF FORMING INSULATING FILM BY USING ATOMIC LAYER DEPOSITION

(71) Applicants: Samsung Electronics Co., Ltd., Suwon-si (KR); AJOU UNIVERSITY INDUSTRY-ACADEMIC COOPERATION FOUNDATION, Suwon-si (KR)

(72) Inventors: Jeonggyu SONG, Suwon-si (KR); Ilkwon OH, Gunpo-si (KR); Beomseok KIM, Hwaseong-si (KR); Jooho LEE, Suwon-si (KR); Wonsik CHOI, Hwaseong-si (KR); Byungjun WON, Suwon-si (KR); Minjeong RHEE, Yongin-si (KR)

(73) Assignees: Samsung Electronics Co., Ltd., Suwon-si (KR); AJOU UNIVERSITY INDUSTRY-ACADEMIC COOPERATION FOUNDATION, Suwon-si (KR)

(21) Appl. No.: 18/504,712

(22) Filed: Nov. 8, 2023

(30) Foreign Application Priority Data
Jun. 21, 2023 (KR) 10-2023-0079932

(51) Int. Cl. H01L 21/02; C23C 16/34; C23C 16/40; C23C 16/455

(52) U.S. Cl. CPC H01L 21/0228; C23C 16/34; C23C 16/40; C23C 16/45527

(57) ABSTRACT

Provided is a method of forming an insulating film on a substrate by using atomic layer deposition (ALD). The method of forming an insulating film on a substrate by using ALD includes transferring a deposition-hindering material to the substrate, and depositing a first material layer by transferring a first precursor to the deposition-hindering material, wherein the deposition-hindering material includes an organic ligand, and the first precursor includes an alkoxide ligand.

### CROSS-REFERENCE TO RELATED APPLICATION

This application is based on and claims priority under 35 U.S.C. § 119 to Korean Patent Application No. 10-2023-0079932, filed on Jun. 21, 2023, in the Korean Intellectual Property Office, the disclosure of which is incorporated by reference herein in its entirety.

### BACKGROUND

### 1. Field

The disclosure relates to a method of forming an insulating film by using atomic layer deposition.

### 2. Description of the Related Art

Atomic layer deposition is used as a process of forming an insulating film of a capacitor. Atomic layer deposition is one of chemical deposition methods capable of adjusting the thickness of an insulating film or a thin film by adjusting the number of cycles, that is, capable of controlling a monoatomic layer.

Recently, atomic layer deposition using a deposition-hindering material has been studied as a method of finely adjusting the thickness of an insulating film or a thin film.

### SUMMARY

Provided is a method of forming an insulating film by using atomic layer deposition.

Additional aspects will be set forth in part in the description which follows and, in part, will be apparent from the description, or may be learned by practice of the presented embodiments.

According to an aspect of the disclosure, a method of forming an insulating film on a substrate by using atomic layer deposition (ALD) includes transferring a deposition-hindering material to a surface of the substrate, and depositing a first material layer by transferring a first precursor to the surface of the substrate including the deposition-hindering material, wherein the deposition-hindering material includes an organic ligand, and the first precursor includes an alkoxide ligand.

The organic ligand may include a cyclopentadienyl ligand.

The method may further include purging the first precursor.

The substrate may include at least one of Al, Si, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, Hf, Ta, W, Re, Os, Ir, Pt, Au, or a nitride or oxide thereof.

The cyclopentadienyl ligand may have higher reaction energy than a corresponding amide ligand.

The first material layer may include at least one of an oxide or nitride.

The first precursor may include at least one of H, Li, Be, B, C, N, O, F, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, or U.

The method may further include forming a plurality of material layers by repeatedly performing the forming of the first material layer in a plurality of cycles.

The insulating film may be an oxide including at least one of Mg, Al, Si, Ti, Sr, Zr, Ba, or Hf.

The insulating film may be a nitride including at least one of Mg, Al, Si, Ti, Sr, Zr, Ba, or Hf.

The insulating film may have a single-layer structure, or the method may include depositing a second material layer on the first material layer such that the insulating film has a multi-layer structure in which different materials are stacked.

The insulating film may be grown on the substrate.

The first material layer may be formed to a thickness within a range from 0.01 nanometers (nm) to 0.1 nm.

The insulating film may be formed to a thickness of tens of nanometers (nm) or less.

A thickness of the first material layer may be determined by the first precursor.

According to another aspect of the disclosure, a semiconductor device includes an insulating film provided by the method of forming an insulating film.

### BRIEF DESCRIPTION OF THE DRAWINGS

The above and other aspects, features, and advantages of certain embodiments will be more apparent from the following description taken in conjunction with the accompanying drawings, in which:

FIGS. 1A to 1D are views for describing atomic layer deposition (ALD), according to at least one embodiment;

FIGS. 2A to 2C are views for describing a method of forming an insulating film by using a deposition-hindering material, according to at least one embodiment;

FIGS. 3A and 3B are views illustrating a result of comparing thicknesses of deposited insulating films, according to at least one embodiment;

FIG. 4 is a view for describing reaction energy of a precursor and a deposition-hindering material, according to at least one embodiment;

FIGS. 5A and 5B are views for describing doping of an insulating film using fine thickness adjustment of an insulating film; and

FIGS. 6A and 6B are views for describing step coverage of an insulating film deposited on a lower electrode.

### DETAILED DESCRIPTION

Reference will now be made in detail to embodiments, examples of which are illustrated in the accompanying drawings, wherein like reference numerals refer to like elements throughout. In this regard, the present embodiments may have different forms, sizes of elements may be exaggerated for clarity and convenience of explanation, and the present embodiments should not be construed as being limited to the descriptions illustrated herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

When a first element is “on ˜” or “over” a second element, it may include a case where the first element contacts the second element and is directly located on the top, bottom, left, or right of the second element, and a case where the first element does not contact the second element and is located on the top, bottom, left, or right of the second element with a third element therebetween. The singular forms “a,” “an,” and “the” are intended to include the plural forms as well, unless the context clearly indicates otherwise. When a part “includes” an element, another element may be further included, rather than excluding the existence of the other element, unless otherwise described.

The use of the terms “a” and “an,” and “the” and similar referents in the context of describing the disclosure is to be construed to cover both the singular and the plural. The steps of all methods described herein may be performed in any suitable order unless otherwise indicated herein or otherwise clearly contradicted by context, and are not limited to the described order.

When the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

The use of any and all examples, or exemplary language provided herein, is intended merely to better describe the disclosure and does not pose a limitation on the scope of the disclosure unless otherwise claimed.

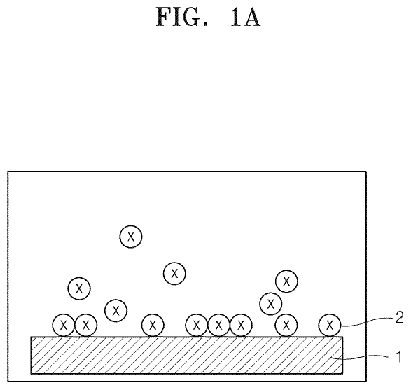

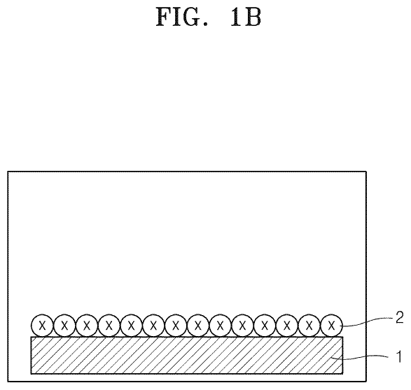

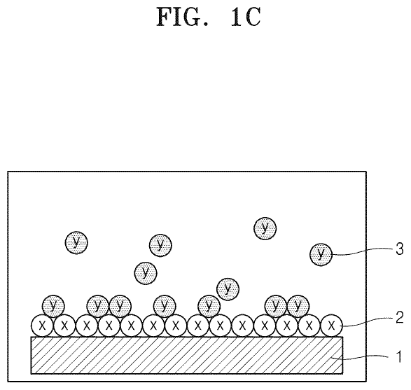

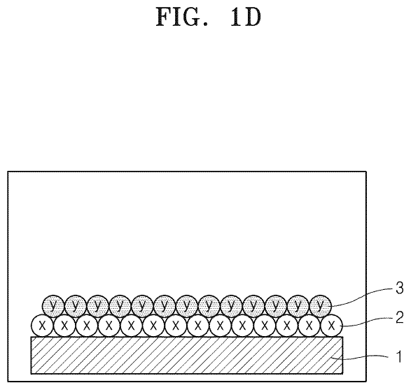

FIGS. 1A to 1D are views for describing atomic layer deposition (ALD), according to at least one embodiment.

ALD refers to a nano thin-film deposition technique using the phenomenon of a monoatomic layer that is chemically attached during a manufacturing process, such as a semiconductor manufacturing process. Fine layer-by-layer deposition of an atomic layer thickness is possible by alternately performing adsorption and substitution of molecules or atoms on a surface of a semiconductor substrate, oxide and metal thin films may be stacked as thin as possible, and a process may be performed at a lower temperature (500° C. or less) than chemical vapor deposition (CVD) in which particles formed by a chemical reaction of injected gas are deposited on a surface of a substrate.

Referring to FIG. 1A, precursors X may be transferred to a semiconductor substrate 1. In at least example, the semiconductor substrate 1 may include at least one material selected from among Al, Si, Sc. Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, Hf, Ta, W. Re, Os, Ir, Pt, and Au, or may include a material including nitride or oxide in the at least one material. However, the disclosure is not limited thereto.

The precursors X may include selected atoms. For example, the precursors X may include any kind of atoms capable of ALD.

Referring to FIG. 1B, the transferred precursors X are deposited on a surface of the semiconductor substrate. For example, the precursors X may be coupled to a portion of the surface of the semiconductor substrate which is relatively unstable due to a weak bonding force (dangling bond) of the surface of the semiconductor substrate.

After the precursors X saturate the surface of the semiconductor substrate (e.g., are deposited on the entire surface of the semiconductor substrate), the remaining precursors X may float in the air and may be purged (removed) (e.g., by inert gas such as nitrogen or argon).

Referring to FIGS. 1C and 1D, precursors Y may be transferred to and deposited on the surface on which the precursors X are deposited. The precursors Y may include any kind of atoms capable of ALD, and thereby layer-by-layer deposition is possible. In at least some embodiments, the precursors Y may include the same composition and/or deposited atoms as the precursors X. and thereby each atomic layer of the resulting film may comprise the same (or substantially similar) composition. These examples may also be referred to as a single-layer structure. In at least one embodiment, the precursors Y may include a different composition and/or deposited atoms as the precursors X, and thereby the resulting structure may include a stack of different materials. These examples may also be referred to as a multi-layer structure.

In at least some embodiments, wherein the crystalline structure of the substrate induces an ordered structure in the material layers, the resulting insulating film may be referred to as being grown on the substrate.

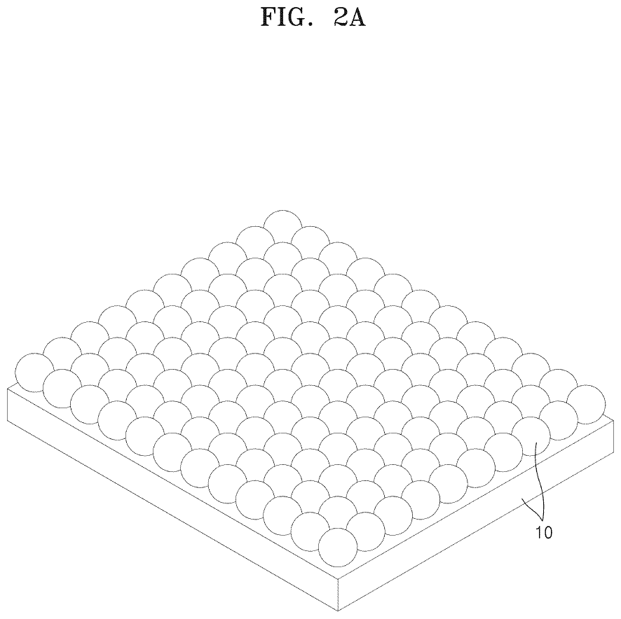

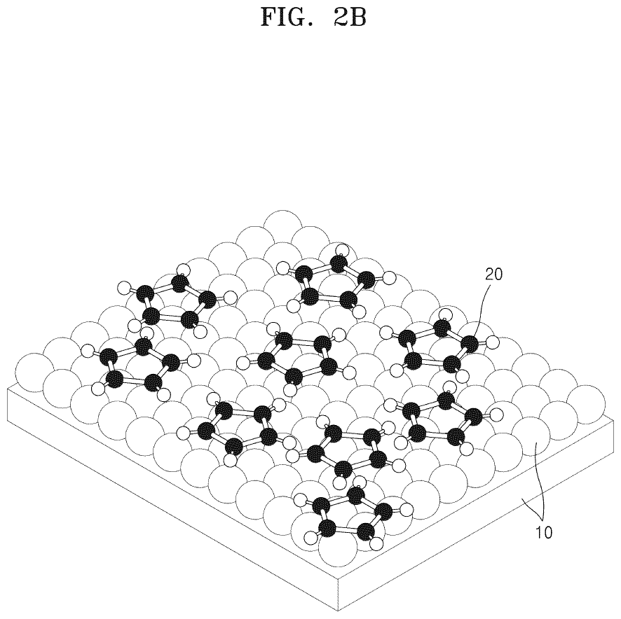

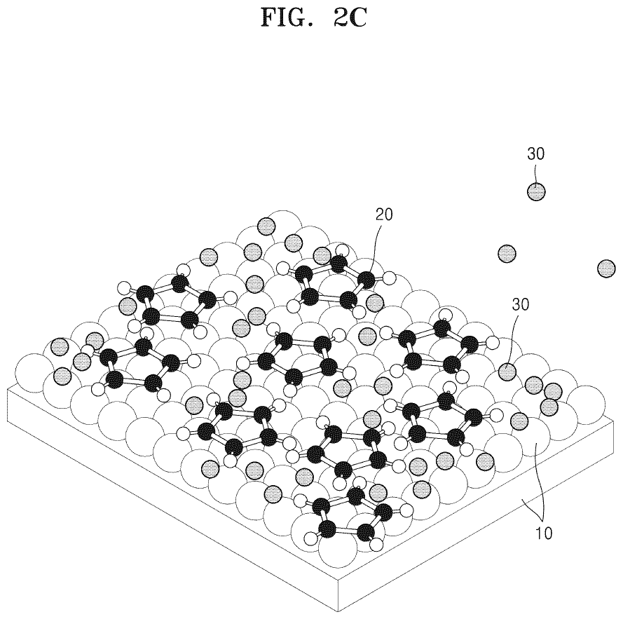

FIGS. 2A to 2C are views for describing a method of forming an insulating film by using a deposition-hindering material, according to at least one embodiment.

Referring to FIG. 2A, a certain material may be deposited on the substrate 10. For example, a certain material may be transferred to a surface of the substrate 10, and the certain material may be deposited on a portion of the surface of the substrate 10 which is relatively unstable. For example, the substrate and the certain material may be coupled to each other by a dangling bond.

The substrate 10 may be the same as (and/or substantially similar to) the semiconductor substrate 1. For example, the substrate 10 may include at least one material selected from among Al, Si, Sc, Ti, V, Cr, Mn, Fc, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, Hf, Ta, W, Re, Os, Ir, Pt, and Au, or may include a material including nitride or oxide in the at least one material. However, the disclosure is not limited thereto.

Referring to FIG. 2B, a deposition-hindering material 20 may be transferred to the substrate 10. The deposition-hindering material 20 may include a ligand having a higher reaction energy than other ligands used during the ALD.

For example, the deposition-hindering material 20 may include, but is not limited to, a cyclopentadienyl ligand, wherein the cyclopentadienyl ligand included in the deposition-hindering material 20 may have higher reaction energy than an amide ligand.

A material having higher reaction energy has a lower degree of bonding to an upper surface or a lower surface than a material having lower reaction energy. Because the deposition-hindering material 20 has higher reaction energy, the deposition-hindering material 20 has a low bonding force with the substrate 10 located under the deposition-hindering material 20 and a first material layer deposited on the deposition-hindering material 20. The low bonding force to the upper surface or the lower surface may enable fine thickness control of an insulating film or a thin film, which will be described below in further detail.

Referring to FIG. 2C, a first precursor 30 may be transferred to the substrate 10 and the deposition-hindering material 20.

The first precursor 30 may include, but is not limited to, an alkoxide ligand. The first precursor 30 has higher reaction energy than a material for forming the substrate 10. A precursor material having higher reaction energy has a lower degree of bonding to an upper surface or a lower surface than a material having lower reaction energy. The first precursor 30 may be the same as (and/or substantially similar to) the precursor X.

The first precursor 30 may include at least one of, but not limited to, H, Li, Be, B, C, N, O, F, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg. TI, Pb, Bi, Po, Fr, Ra, Ac, Th, Pa, and U. For example, in at least one embodiment, the first precursor may include a metal atom (e.g., at least one of Li, Bc, B, Na, Mg, Al, Si, K, Ca, Sc, Ti, V, Cr, Mn, Fe, Co, Ni, Cu, Zn, Ga, Ge, Rb, Sr. Y, Zr. Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, TI, Pb, Bi, Po, Fr, Ra, Ac. Th, Pa, U, etc.) and an organic ligand, wherein the organic ligand includes at least one of (H, C, N, O, F, etc.).

For example, the first precursor 30 may include Al(CH₃)₂(OC₃H₇). However, the disclosure is not limited thereto.

The depositing of the first precursor 30 enables a first material layer to be formed, and the first material layer may include at least one of an oxygen element and a nitrogen element. Also, the first material layer may include, but is not limited to, aluminum oxide. Subsequently, as illustrated above, a second material layer may be formed on the first material layer. In at least one embodiment, the second material layer may be, e.g., a zirconium oxide layer.

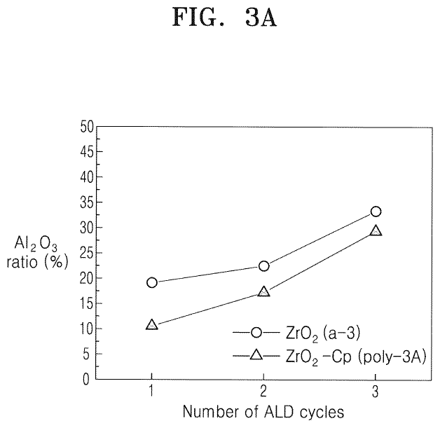

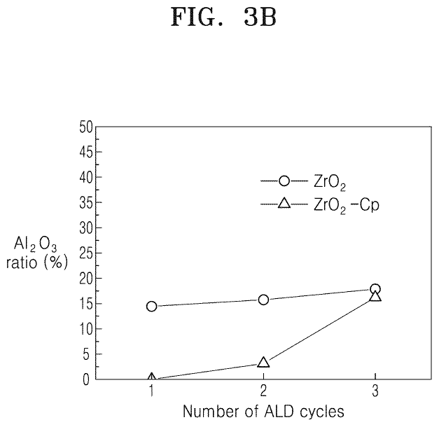

FIGS. 3A and 3B are views illustrating a result of comparing thicknesses of deposited insulating films, according to at least one embodiment.

Referring to FIGS. 3A and 3B, in the same number of deposition cycles, a degree of deposition of a material layer when a cyclopentadienyl ligand is deposited on zirconium oxide (ZrO₂—Cp) is lower than that when an insulating film includes only zirconium oxide (ZrO₂). For example, a degree of deposition of Al₂O₃ is lower. As described above, the cyclopentadienyl ligand may function as a deposition-hindering material. When the deposition-hindering material is transferred and deposited, a target material may be deposited at a lower level even with the same number of deposition cycles, and in this case, a thickness of a target thin film or insulating film may be finely adjusted while still maintaining even (e.g., consistent) coverage.

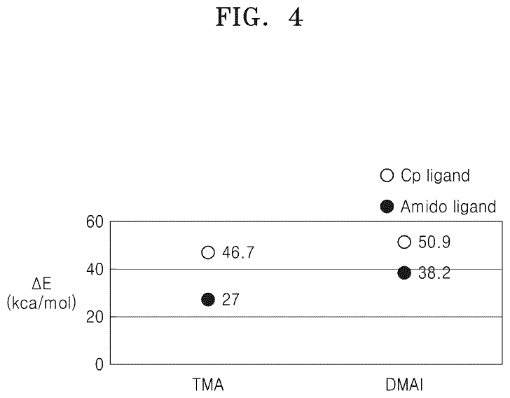

FIG. 4 is a view for describing reaction energy of a precursor and a deposition-hindering material, according to at least one embodiment.

Referring to FIG. 4, when a precursor is Al(CH₃)₂(OC₃H₇) (dimethylalmuninum isopropoxide-DMAI), the precursor may have higher reaction energy than when the precursor is trimethyl aluminum (TMA). Likewise, a cyclopentadienyl ligand may have higher reaction energy than an amide ligand.

As described above, a material having higher reaction energy has a lower bonding force to an upper surface or a lower surface, that is, an adjacent material, and thus, may have a lower deposition rate relative to the same number of depositions.

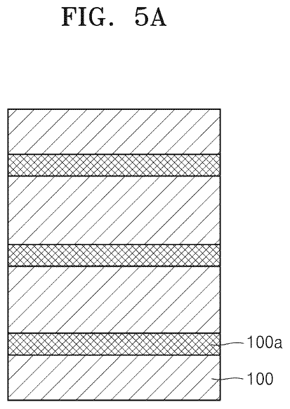

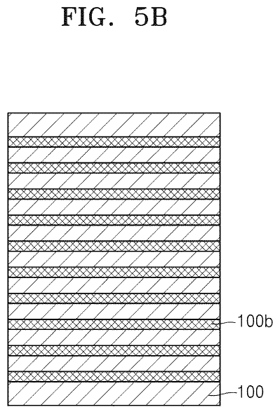

FIGS. 5A and 5B are views for describing doping of an insulating film using fine thickness adjustment of an insulating film.

Referring to FIGS. 5A and 5B, doping layers 100a and 100b may be formed on an insulating film 100 by using a certain dopant. In these cases, when thicknesses of the doping layers are compared, when fine thickness adjustment of a target layer is possible by using a deposition-hindering material and a ligand having high reaction energy, the finer doping layer 100b may be formed on the unit insulating film 100. As such, the thickness of the finer doping layer 100b is determined by the presence of the deposition-hindering material, and the surface concentration thereof.

In these cases, the insulating film may include at least one of, but not limited to, hafnium oxide, zirconium oxide, and hafnium zirconium oxide.

For example, the insulating film may be an oxide including at least one of Mg, Al, Si, Ti, Sr. Zr. Ba, and Hf, or in another embodiment, the insulating film may be a nitride including at least one of Mg, Al, Si, Ti, Sr, Zr, Ba, and Hf. However, the disclosure is not necessarily limited thereto.

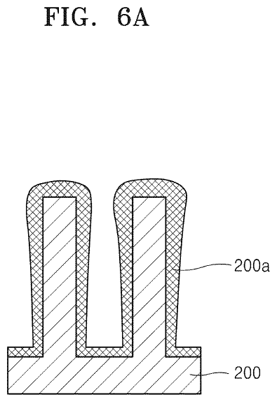

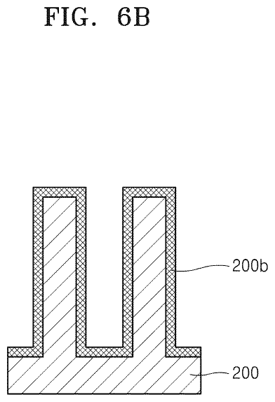

FIGS. 6A and 6B are views for describing step coverage of an insulating film deposited on a lower electrode.

Referring to FIGS. 6A and 6B, certain thin films 200a and 200b may be formed on a lower electrode 200 of a capacitor. In these cases, when a thickness and step coverage of a thin film are compared, the finer thin film 200b may be formed when fine thickness adjustment of a target thin film is possible by using a deposition-hindering material and a ligand having high reaction energy. More specifically, as the deposition-hindering material is likely to accumulate in areas wherein the precursors (e.g., X and Y) would also accumulate, the deposition-hindering material may reduce the thickness of the thin film 200b in those areas. For example, the thickness of the thin film 200b (and/or the material layers contained therein) is determined by the presence of the deposition-hindering material, and the surface concentration thereof.

In these cases, the insulating film may include at least one of, but not limited to, hafnium oxide, zirconium oxide, and hafnium zirconium oxide.

A semiconductor device including an insulating film provided by using the method of forming an insulating film may be formed.

According to at least one embodiment, a method of forming an insulating film on a substrate by using ALD includes transferring a deposition-hindering material to the substrate and depositing a first material layer by transferring a first precursor to the deposition-hindering material. As such, because a deposition-hindering material having higher reaction energy than other materials may prevent formation of a material layer, a thickness of an insulating film or a thin film may be finely adjusted. The fine thickness adjustment of the insulating film or the thin film may be applied to fine dopant doping in the insulating film.

While a method of forming a thin film and a semiconductor device using the method have been descried with reference to the embodiments shown in the drawings, these are examples and it will be understood by one of ordinary skill in the art that various changes in form and details may be made therein without departing from the scope of the disclosure. The disclosed embodiments should be considered in descriptive sense only and not for purposes of limitation. Therefore, the scope of the disclosure is defined not by the detailed description of the disclosure but by the appended claims, and all differences within the scope will be construed as being included in the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A method of forming an insulating film on a substrate by using atomic layer deposition (ALD), the method comprising:
transferring a deposition-hindering material to a surface of the substrate; and
depositing a first material layer by transferring a first precursor to the surface of the substrate including the deposition-hindering material,
wherein the deposition-hindering material comprises an organic ligand, and
the first precursor comprises an alkoxide ligand.

2. The method of claim 1, wherein the organic ligand comprises a cyclopentadienyl ligand.

3. The method of claim 1, further comprising:
purging the first precursor.

4. The method of claim 1, wherein the substrate comprises at least one of Al, Si, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, Hf, Ta, W, Re, Os, Ir, Pt, Au, or a nitride or oxide thereof.

5. The method of claim 2, wherein the cyclopentadienyl ligand has higher reaction energy than a corresponding amide ligand.

6. The method of claim 1, wherein the first material layer comprises at least one of an oxide or a nitride.

7. The method of claim 1, wherein the first precursor comprises at least one of H, Li, Be, B, C, N, O, F, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, or U.

8. The method of claim 1, further comprising:
forming a plurality of material layers by repeatedly performing the forming of the first material layer in a plurality of cycles.

9. The method of claim 1, wherein the insulating film is an oxide comprising at least one of Mg, Al, Si, Ti, Sr, Zr, Ba, or Hf.

10. The method of claim 1, wherein the insulating film is a nitride comprising at least one of Mg, Al, Si, Ti, Sr, Zr, Ba, or Hf.

11. The method of claim 1, wherein the insulating film has a single-layer structure.

12. The method of claim 1, further comprising:
depositing a second material layer on the first material layer such that the insulating film has a multi-layer structure in which different materials are stacked.

13. The method of claim 1, wherein the insulating film is grown on the substrate.

14. The method of claim 1, wherein the first material layer is formed to a thickness within a range from 0.01 nanometers (nm) to 0.1 nm.

15. The method of claim 1, wherein the insulating film is formed to a thickness of tens of nanometers (nm) or less.

16. The method of claim 1, wherein a thickness of the first material layer is determined by the first precursor.

17. A semiconductor device comprising the insulating film provided by the method of forming the insulating film according to claim 1.
